(19) United States
(12) Patent Application Publication
(10) Pub. No.: US 2026/0135568 A1
(43) Pub. Date: May 14, 2026

(54) Recording module and its sigma-delta modulator (SDM)

(71) Applicant: REALTEK SEMICONDUCTOR CORPORATION, HSINCHU (TW)

(72) Inventors: CHIA-LING CHANG, HSINCHU (TW); PEI-CHUN LIAO, HSINCHU (TW)

(21) Appl. No.: 19/374,429

(22) Filed: Oct. 30, 2025

(30) Foreign Application Priority Data
Nov. 8, 2024 (TW) 113143082

(51) Int. Cl. H03M 3/00

(52) U.S. Cl. CPC H03M 3/412; H03M 3/32; H03M 3/50

(57) ABSTRACT

A sigma-delta modulator (SDM) is coupled to a driving circuit through a first input terminal and receives an intermediate signal outputted by the driving circuit. The SDM includes an operational amplifier, first and second sampling capacitors, and first and second integrating capacitors. The operational amplifier has a second input terminal, a third input terminal, and an output terminal. Two terminals of the first sampling capacitor are respectively coupled to the first and second input terminals for sampling the intermediate signal. Two terminals of the second sampling capacitor are respectively coupled to the first and second input terminals for sampling the intermediate signal. Two terminals of the first integrating capacitor are respectively coupled to the second input terminal and the output terminal. Two terminals of the second integrating capacitor are respectively coupled to the second input terminal and the output terminal.

### BACKGROUND OF THE INVENTION

### 1. Field of the Invention

The present invention generally relates to sigma-delta modulator (SDM), and more particularly, to an SDM with adjustable resolution.

### 2. Description of Related Art

Reference is made to FIG. 1, which is a circuit diagram of a conventional sigma-delta modulator (SDM). The SDM 100 includes an integrator 110 and an integrator 120. The integrator 110 includes an operational amplifier 112, a capacitor C1, a capacitor C2, and switches SW1 to SW4.

The integrator 110 receives an input signal Sin from the input terminal 102 and outputs an output signal Sout from the output terminal of the operational amplifier 112. By means of switching the switches SW1 to SW4, the integrator 110 alternately operates during the sampling phase and the integration phase. During the sampling phase, the switch SW1 and the switch SW3 are turned on and the switch SW2 and the switch SW4 are turned off, causing the capacitor C1 to sample the input signal Sin. During the integration phase, the switch SW1 and the switch SW3 are turned off and the switch SW2 and the switch SW4 are turned on, integrating the sampled result onto the capacitor C2. Vref, V+, and V- are reference voltages. The operating principle of the integrator 110 is well known to people having ordinary skill in the art, so further elaboration is omitted for brevity.

The overall thermal noise of the integrator 110 depends on the size of the capacitor C1: the larger the capacitance value of the capacitor C1, the lower the thermal noise. However, increasing the capacitance value of the capacitor C1 causes an increase in the power consumption of the operational amplifier 112 (to maintain linear operation), which is detrimental to the competitiveness of the circuit.

### SUMMARY OF THE INVENTION

In view of the issues of the prior art, an object of the present invention is to provide a recording module and a sigma-delta modulator (SDM) thereof, so as to make an improvement to the prior art.

According to one aspect of the present invention, an SDM is provided. The SDM is coupled to a driving circuit through a first input terminal and receives an intermediate signal outputted by the driving circuit. The SDM includes an operational amplifier, a first sampling capacitor, a second sampling capacitor, a first integrating capacitor, and a second integrating capacitor. The operational amplifier has a second input terminal, a third input terminal, and an output terminal. The two terminals of the first sampling capacitor are respectively coupled to the first input terminal and the second input terminal, and it is configured to sample the intermediate signal. The two terminals of the second sampling capacitor are respectively coupled to the first input terminal and the second input terminal, and it is configured to sample the intermediate signal. The two terminals of the first integrating capacitor are respectively coupled to the second input terminal and the output terminal. The two terminals of the second integrating capacitor are respectively coupled to the second input terminal and the output terminal.

According to another aspect of the present invention, a recording module is provided. The recording module is applied to an audio device and includes a driving circuit and an SDM. The driving circuit is configured to receive an input signal and generate an intermediate signal. The SDM is coupled to the driving circuit and includes an operational amplifier, a first sampling capacitor, a second sampling capacitor, a first integrating capacitor, and a second integrating capacitor. The operational amplifier has a first input terminal, a second input terminal, and an output terminal. The two terminals of the first sampling capacitor are respectively coupled to the driving circuit and the first input terminal, and it is configured to sample the intermediate signal. The two terminals of the second sampling capacitor are respectively coupled to the driving circuit and the first input terminal, and it is configured to sample the intermediate signal. The two terminals of the first integrating capacitor are respectively coupled to the first input terminal and the output terminal. The two terminals of the second integrating capacitor are respectively coupled to the first input terminal and the output terminal.

The technical means embodied in the embodiments of the present invention can solve at least one of the problems of the prior art. Therefore, compared to the prior art, the present invention can reduce power consumption.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is the circuit diagram of a conventional sigma-delta modulator (SDM).

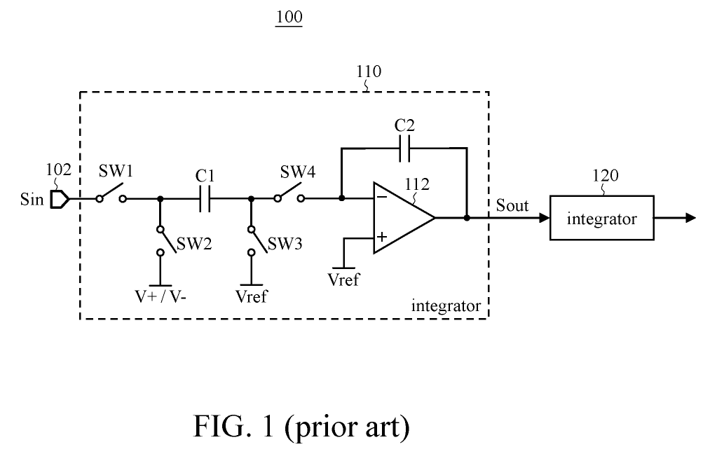

FIG. 2 is a functional block diagram of the audio device 200 according to an embodiment of the present invention.

FIG. 3 is a circuit diagram of the recording module 210 according to an embodiment of the present invention.

FIG. 4 shows the waveforms of multiple clocks of the present invention.

FIG. 5 is the circuit diagram of the SDM 214 according to another embodiment of the present invention.

FIG. 6 is the circuit diagram of the driving circuit according to another embodiment of the present invention.

FIG. 7 is a functional block diagram of the driving circuit according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes a recording module and its sigma-delta modulator (SDM). On account of that some or all elements of the recording module and its SDM could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

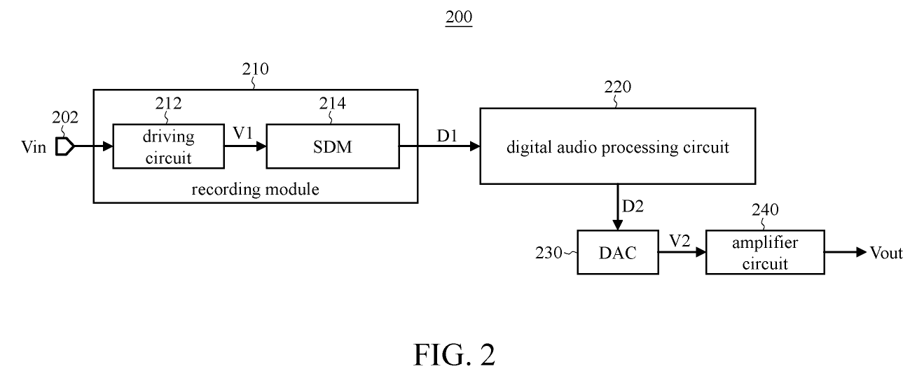

Reference is made to FIG. 2, which is a functional block diagram of the audio device 200 according to an embodiment of the present invention. The audio device 200 includes a recording module 210, a digital audio processing circuit 220, a digital-to-analog converter (DAC) 230, and an amplifier circuit 240, all of which are coupled to each other.

The recording module 210, coupled to the input terminal 202, is used to receive the input signal Vin from the input terminal 202 and to generate the digital code D1. The recording module 210 includes a driving circuit 212 and an SDM 214 that are coupled to each other. The driving circuit 212 is used to enhance the driving capability of the input signal Vin and to generate the intermediate signal V1. The SDM 214 converts the intermediate signal V1 into the digital code D1.

The digital audio processing circuit 220 is used to perform audio processing, such as filtering and equalization, on the digital code D1 and to generate the digital code D2. The DAC 230 is used to convert the digital code D2 into the intermediate signal V2. The amplifier circuit 240 amplifies the intermediate signal V2 to produce the output signal Vout. The output signal Vout can be outputted to a headphone or a speaker.

In some embodiments, the input signal Vin is generated by a microphone, or inputted into the audio device 200 through the line-in interface of the audio device 200.

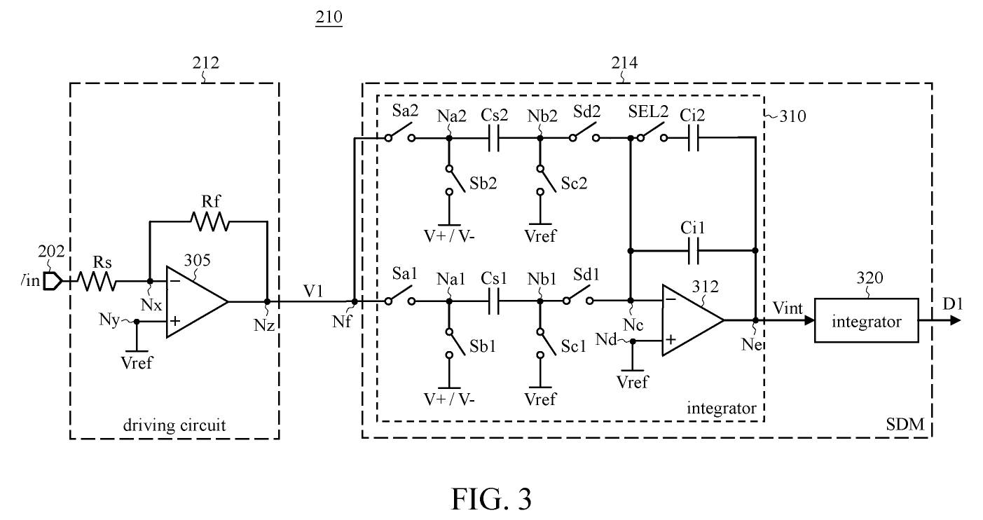

Reference is made to the FIG. 3, which is a circuit diagram of the recording module 210 according to an embodiment of the present invention. The driving circuit 212 includes an operational amplifier 305, a resistor Rf, and a resistor Rs. One terminal of the resistor Rs is coupled or electrically connected to the input terminal 202 to receive the input signal Vin; the other terminal of the resistor Rs is coupled or electrically connected to an input terminal Nx of the operational amplifier 305 (e.g., the inverting input terminal). One terminal of the resistor Rf is coupled or electrically connected to the input terminal Nx of the operational amplifier 305; the other terminal of the resistor Rf is coupled or electrically connected to the output terminal Nz of the operational amplifier 305. The input terminal Ny of the operational amplifier 305 (e.g., the non-inverting input terminal) is coupled or electrically connected to the reference voltage Vref.

The SDM 214 includes an integrator 310 and an integrator 320. It should be noted that the two-stage integrator of the SDM 214 is for illustrative purposes only and is not intended to limit the scope of the invention. In some embodiments, the SDM 214 can include more integrators. The integrator 310 is the first-stage integrator of the SDM 214.

The integrator 310 has an input terminal Nf and an output terminal Ne (i.e., the output terminal of an operational amplifier 312), and includes the operational amplifier 312, a sampling capacitor Cs1, a sampling capacitor Cs2, an integrating capacitor Ci1, an integrating capacitor Ci2, a switch Sa1, a switch Sb1, a switch Sc1, a switch Sd1, a switch Sa2, a switch Sb2, a switch Sc2, a switch Sd2, and a switch SEL2. The input terminal Nd of the operational amplifier 312 (e.g., the non-inverting input terminal) is coupled or electrically connected to the reference voltage Vref; the output terminal Ne of the operational amplifier 312 is coupled or electrically connected to the integrator 320.

The two terminals of the sampling capacitor Cs1 are the node Na1 and the node Nb1, respectively. The sampling capacitor Cs1 is used to sample the intermediate signal V1. One terminal of the switch Sa1 is coupled or electrically connected to the input terminal Nf (i.e., the output terminal Nz); another terminal of the switch Sa1 is coupled or electrically connected to the node Na1. One terminal of the switch Sb1 is coupled or electrically connected to the node Na1; another terminal of the switch Sb1 is coupled or electrically connected to a reference voltage V+ or a reference voltage V-. One terminal of the switch Sc1 is coupled or electrically connected to the node Nb1; another terminal of the switch Sc1 is coupled or electrically connected to a reference voltage Vref. One terminal of the switch Sd1 is coupled or electrically connected to the node Nb1; another terminal of the switch Sd1 is coupled or electrically connected to the input terminal Nc of the operational amplifier 312 (e.g., the inverting input terminal).

The two terminals of the sampling capacitor Cs2 are the node Na2 and the node Nb2, respectively. The sampling capacitor Cs2 is used to sample the intermediate signal V1. One terminal of the switch Sa2 is coupled or electrically connected to the input terminal Nf (i.e., the output terminal Nz); another terminal of the switch Sa2 is coupled or electrically connected to the node Na2. One terminal of the switch Sb2 is coupled or electrically connected to the node Na2; another terminal of the switch Sb2 is coupled or electrically connected to the reference voltage V+ or the reference voltage V-. One terminal of the switch Sc2 is coupled or electrically connected to the node Nb2; another terminal of the switch Sc2 is coupled or electrically connected to the reference voltage Vref. One terminal of the switch Sd2 is coupled or electrically connected to the node Nb2; another terminal of the switch Sd2 is coupled or electrically connected to the input terminal Nc of the operational amplifier 312.

One terminal of the integrating capacitor Ci1 is coupled or electrically connected to the input terminal Nc of the operational amplifier 312; the other terminal of the integrating capacitor Ci1 is coupled or electrically connected to the output terminal Ne of the operational amplifier 312. One terminal of the integrating capacitor Ci2 is coupled or electrically connected to the switch SEL2; the other terminal of the integrating capacitor Ci2 is coupled or electrically connected to the output terminal Ne of the operational amplifier 312.

One terminal of the switch SEL2 is coupled or electrically connected to the input terminal Nc of the operational amplifier 312; another terminal of the switch SEL2 is coupled or electrically connected to the integrating capacitor Ci2.

It should be noted that the circuit in FIG. 3 is an embodiment corresponding to single-ended signals, and the reference voltage Vref may be ground. People having ordinary skill in the art can apply the recording module 210 to differential signals based on FIG. 3 and the above discussion, and the reference voltage Vref may be the common-mode voltage of the differential signal.

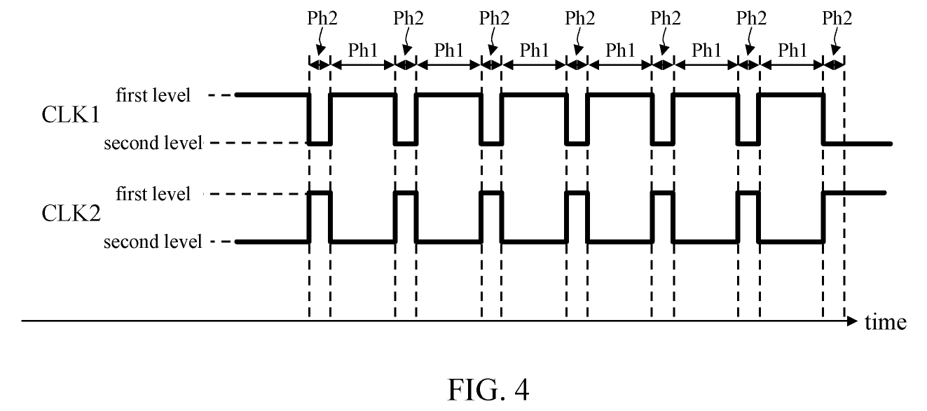

The SDM 214 operates according to the non-overlapping clocks CLK1 and CLK2 (as shown in FIG. 4). That is to say, the clock CLK1 and the clock CLK2 are not at the first level (e.g., high level) or not at the second level (e.g., low level) at the same time.

The SDM 214 can operate in (1) a high-resolution mode or (2) a low-resolution mode.

### 1 The high-resolution mode

The switch SEL2 is turned on, causing the integrating capacitor Ci1 and the integrating capacitor Ci2 to be connected in parallel, and thus the capacitance value of the equivalent integrating capacitor of the integrator 310 is substantially equal to the sum of the capacitance value of the integrating capacitor Ci1 and the capacitance value of the integrating capacitor Ci2. In the high-resolution mode, the integration coefficient of the integrator 310 is (Cs1+Cs2)/(Ci1+Ci2).

During the sampling phase Ph1 (as shown in FIG. 4, the clock CLK1 is at the first level and the clock CLK2 is at the second level), the switch SEL2, the switch Sa1, the switch Sa2, the switch Sc1, and the switch Sc2 are turned on, and the switch Sb1, the switch Sb2, the switch Sd1, and the switch Sd2 are turned off, so that the sampling capacitor Cs1 and the sampling capacitor Cs2 sample the intermediate signal V1 at substantially the same time.

During the integration phase Ph2 (as shown in FIG. 4, the clock CLK1 is at the second level and the clock CLK2 is at the first level), the switch Sa1, the switch Sa2, the switch Sc1, and the switch Sc2 are turned off, and the switch SEL2, the switch Sb1, the switch Sb2, the switch Sd1, and the switch Sd2 are turned on, causing the integrator 310 to perform the integration operation (at this time, the integrating capacitor Ci1 and the integrating capacitor Ci2 both participate in the integration operation) to generate the integration signal Vint.

### 2 The low-resolution mode

The switch SEL2, the switch Sa2, the switch Sb2, the switch Sc2, and the switch Sd2 are turned off, causing the sampling capacitor Cs2 not to participate in signal sampling, and the integrating capacitor Ci2 not to participate in integration operation. In this case, the integrating capacitor Ci1 is not connected in parallel with the integrating capacitor Ci2. Therefore, the capacitance value of the equivalent integrating capacitor of the integrator 310 is substantially equal to the capacitance value of the integrating capacitor Ci1. In the low-resolution mode, the integration coefficient of the integrator 310 is Cs1/Ci1.

During the sampling phase Ph1, the switch Sa1 and the switch Sc1 are turned on, and the switch Sb1 and the switch Sd1 are turned off, so that the sampling capacitor Cs1 samples the intermediate signal V1.

During the integration phase Ph2, the switch Sa1 and the switch Sc1 are turned off, and the switch Sb1 and the switch Sd1 are turned on, causing the integrator 310 to perform the integration operation to generate the integration signal Vint. During the integration phase Ph2, the integrating capacitor Ci2 does not participate in the integration operation; only the integrating capacitor Ci1 participates in the integration operation.

It should be noted that the SDM 214 can operate equivalently based on only the clock CLK1 or the clock CLK2.

As discussed above, the integrator 310 has a larger equivalent integrating capacitor (Ci1+Ci2) in the high-resolution mode, and a smaller equivalent integrating capacitor (Ci1) in the low-resolution mode. That is to say, the SDM 214 has a lower thermal noise in the high-resolution mode (but a higher power consumption), while the SDM 214 has a higher thermal noise in the low-resolution mode (but a lower power consumption). Therefore, the SDM 214 of the present invention can determine the operation mode according to actual needs, so as to timely reduce the overall power consumption of the audio device 200. For example, when a certain application scenario has a higher tolerance for thermal noise, the audio device 200 can operate in a low-resolution mode to save power.

The ratio of the capacitance values of the sampling capacitor Cs1, the sampling capacitor Cs2, the integrating capacitor Ci1, and the integrating capacitor Ci2 may be: Cs1:Cs2=Ci1:Ci2=X:Y (X and Y are positive integers). In this way, the power consumption of the integrator 310 in the low-resolution mode is substantially X/(X+Y) times the power consumption in the high-resolution mode, and the integration coefficient of the integrator 310 is the same in both modes. In some embodiments, X=Y=1.

In some embodiments, the sum of the capacitance value of the sampling capacitor Cs1 and the capacitance value of the sampling capacitor Cs2 substantially equals the capacitance value of the capacitor C1, and the sum of the capacitance value of the integrating capacitor Ci1 and the capacitance value of the integrating capacitor Ci2 substantially equals the capacitance value of the capacitor C2. In other words, in the high-resolution mode, the power consumption of the integrator 310 is substantially the same as the power consumption of the integrator 110. However, in the low-resolution mode, the power consumption of the integrator 310 is less than the power consumption of the integrator 110.

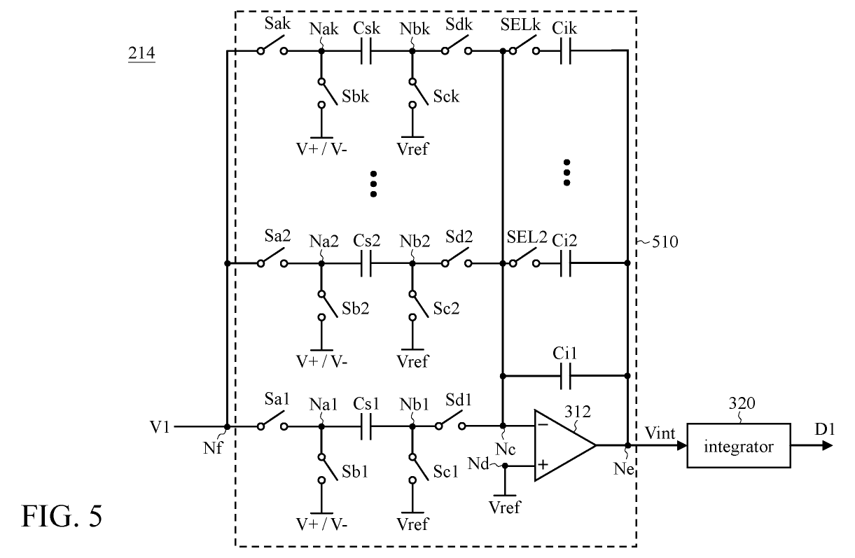

Reference is made to FIG. 5, which is the circuit diagram of the SDM 214 according to another embodiment of the present invention. The SDM 214 contains an integrator 510 and an integrator 320. The integrator 510 is similar to the integrator 310, except that the integrator 510 includes k sampling capacitors (Cs1, Cs2, …, Csk) and k integrating capacitors (Ci1, Ci2, …, Cik) (k>2). The two terminals of the sampling capacitor Csk are the node Nak and the node Nbk, respectively.

One terminal of the switch Sak is coupled or electrically connected to the input terminal Nf (more specifically, the output terminal Nz of the operational amplifier 305); another terminal of the switch Sak is coupled or electrically connected to the node Nak. One terminal of the switch Sbk is coupled or electrically connected to the node Nak; another terminal of the switch Sbk is coupled or electrically connected to the reference voltage V+ or the reference voltage V-. One terminal of the switch Sck is coupled or electrically connected to the node Nbk; another terminal of the switch Sck is coupled or electrically connected to the reference voltage Vref. One terminal of the switch Sdk is coupled or electrically connected to the node Nbk; another terminal of the switch Sdk is coupled or electrically connected to the input terminal Nc of the operational amplifier 312.

One terminal of the integrating capacitor Cik is coupled or electrically connected to the switch SELk; the other terminal of the integrating capacitor Cik is coupled or electrically connected to the output terminal Ne of the operational amplifier 312. One terminal of the switch SELk is coupled or electrically connected to the input terminal Nc of the operational amplifier 312; another terminal of the switch SELk is coupled or electrically connected to the integrating capacitor Cik.

Because the integrator 510 contains more sampling capacitors and integrating capacitors, the integrator 510 can adjust the resolution and power consumption more precisely than the integrator 310.

In some embodiments, the capacitance values of the sampling capacitors Cs1, Cs2, …, Csk are substantially the same, and the capacitance values of the integrating capacitors Ci1, Ci2, …, Cik are substantially the same.

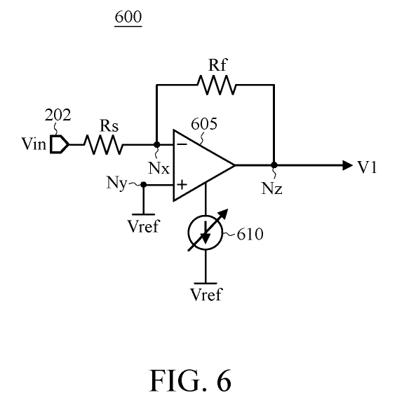

Reference is made to FIG. 6, which is the circuit diagram of the driving circuit according to another embodiment of the present invention. The driving circuit 600 includes an operational amplifier 605, a current source 610, the resistor Rf, and the resistor Rs. The current source 610 provides a bias current to the operational amplifier 605. The driving circuit 212 in FIG. 2 can also be embodied by the driving circuit 600.

In some embodiments, when the resolution of the SDM 214 is relatively low (i.e., the equivalent sampling capacitance value of the integrator 310 or the integrator 510 is relatively small), the power consumption of the driving circuit 600 can be reduced by decreasing the current provided by the current source 610. That is to say, the current source 610 is adjustable, and the magnitude of the current source 610 is proportional to the equivalent sampling capacitance value of the integrator.

For example, when the integrator 310 simultaneously uses the sampling capacitor Cs1 and the sampling capacitor Cs2 for sampling (i.e., the high-resolution mode, where the equivalent sampling capacitance value equals Cs1+Cs2), the current source 610 provides a first bias current; when the integrator 310 uses only the sampling capacitor Cs1 for sampling (i.e., the low-resolution mode, where the equivalent sampling capacitance value equals Cs1), the current source 610 provides a second bias current. In some embodiments, the first bias current is greater than the second bias current.

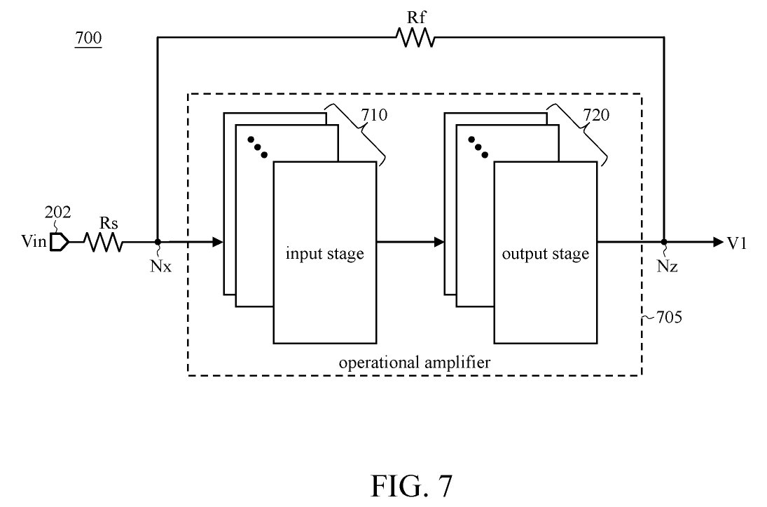

Reference is made to the FIG. 7, which is a functional block diagram of the driving circuit according to another embodiment of the present invention. The driving circuit 700 includes an operational amplifier 705, the resistor Rf, and the resistor Rs. The operational amplifier 705 has an input terminal Nx (e.g., the inverting input terminal) and an output terminal Nz, and includes multiple input stages 710 and multiple output stages 720. The resistor Rf is coupled or electrically connected between the input terminal Nx and the output terminal Nz. The resistor Rs is coupled or electrically connected between the input terminal 202 and the input terminal Nx.

The driving circuit 212 in FIG. 2 can also be embodied by the driving circuit 700. The output stages 720 may be class-A, class-B, or class-AB. The internal circuits of the input stages 710 and the output stages 720 are well known to people having ordinary skill in the art, so further elaboration is omitted for brevity.

In some embodiments, when the resolution of the SDM 214 is relatively low, the driving capability of the driving circuit 700 can be reduced by connecting fewer of the input stages 710 and/or the output stages 720 in parallel, thereby achieving the purpose of power saving.

For example, when the integrator 310 simultaneously uses the sampling capacitor Cs1 and the sampling capacitor Cs2 for sampling, there are M units connected in parallel among the input stages 710 and/or N units connected in parallel among the output stages 720, where M and N are integers greater than or equal to 2, and M may be equal to or different from N. When the integrator 310 uses only the sampling capacitor Cs1 for sampling, there are X units connected in parallel among the input stages 710 and/or Y units connected in parallel among the output stages 720. X and Y are integers greater than or equal to 1, and X may be equal to or different from Y. In some embodiments, M is greater than X, and N is greater than Y.

In summary, the present invention provides an SDM with adjustable resolution, which can achieve a balance between power consumption and performance (e.g., the tolerance to thermal noise), and enhance the overall competitiveness of the audio device 200.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A sigma-delta modulator (SDM), coupled to a driving circuit through a first input terminal and receiving an intermediate signal outputted by the driving circuit, the SDM comprising:
an operational amplifier having a second input terminal, a third input terminal, and an output terminal;
a first sampling capacitor, wherein two terminals of the first sampling capacitor are respectively coupled to the first input terminal and the second input terminal, and the first sampling capacitor is configured to sample the intermediate signal;
a second sampling capacitor, wherein two terminals of the second sampling capacitor are respectively coupled to the first input terminal and the second input terminal, and the second sampling capacitor is configured to sample the intermediate signal;
a first integrating capacitor, wherein two terminals of the first integrating capacitor are respectively coupled to the second input terminal and the output terminal; and
a second integrating capacitor, wherein two terminals of the second integrating capacitor are respectively coupled to the second input terminal and the output terminal.

2. The SDM of claim 1, wherein the first integrating capacitor and the second integrating capacitor are connected in parallel; during a sampling phase, the first sampling capacitor and the second sampling capacitor sample the intermediate signal; and during an integration phase, the first integrating capacitor and the second integrating capacitor participate in an integration operation.

3. The SDM of claim 2, wherein an integration coefficient of the SDM is a sum of capacitance values of the first sampling capacitor and the second sampling capacitor divided by a sum of capacitance values of the first integrating capacitor and the second integrating capacitor.

4. The SDM of claim 2, wherein two terminals of the first sampling capacitor are a first node and a second node, respectively, two terminals of the second sampling capacitor are a third node and a fourth node, respectively, and the SDM further comprises:
a first switch coupled between the first input terminal and the first node;
a second switch coupled between the first node and a first reference voltage;
a third switch coupled between the second node and a second reference voltage;
a fourth switch coupled between the second node and the second input terminal;
a fifth switch coupled between the first input terminal and the third node;
a sixth switch coupled between the third node and the first reference voltage;
a seventh switch coupled between the fourth node and the second reference voltage;
an eighth switch coupled between the fourth node and the second input terminal; and
a ninth switch coupled between the second input terminal and the second integrating capacitor.

5. The SDM of claim 4, wherein during the sampling phase, the first switch, the third switch, the fifth switch, the seventh switch, and the ninth switch are turned on, and the second switch, the fourth switch, the sixth switch, and the eighth switch are turned off; during the integration phase, the first switch, the third switch, the fifth switch, and the seventh switch are turned off, and the second switch, the fourth switch, the sixth switch, the eighth switch, and the ninth switch are turned on.

6. The SDM of claim 1 further comprising:
a third sampling capacitor, wherein two terminals of the third sampling capacitor are respectively coupled to the first input terminal and the second input terminal; and
a third integrating capacitor, wherein two terminals of the third integrating capacitor are respectively to the second input terminal and the output terminal.

7. The SDM of claim 1, wherein a ratio of the first sampling capacitor to the second sampling capacitor is substantially equal to a ratio of the first integrating capacitor to the second integrating capacitor.

8. The SDM of claim 1, wherein the first integrating capacitor is not connected in parallel with the second integrating capacitor; during a sampling phase, the first sampling capacitor samples the intermediate signal, and the second sampling capacitor does not sample the intermediate signal; and during an integration phase, the first integrating capacitor participates in an integration operation, and the second integrating capacitor does not participate in the integration operation.

9. A recording module applied to an audio device and comprising:
a driving circuit configured to receive an input signal and generate an intermediate signal; and
a sigma-delta modulator (SDM) coupled to the driving circuit and comprising:
an operational amplifier having a first input terminal, a second input terminal, and an output terminal;
a first sampling capacitor, wherein two terminals of the first sampling capacitor are respectively coupled to the driving circuit and the first input terminal, and the first sampling capacitor is configured to sample the intermediate signal;
a second sampling capacitor, wherein two terminals of the second sampling capacitor are respectively coupled to the driving circuit and the first input terminal, and the second sampling capacitor is configured to sample the intermediate signal;
a first integrating capacitor, wherein two terminals of the first integrating capacitor are respectively coupled to the first input terminal and the output terminal; and
a second integrating capacitor, wherein two terminals of the second integrating capacitor are respectively coupled to the first input terminal and the output terminal.

10. The recording module of claim 9, wherein during a sampling phase, the first sampling capacitor and the second sampling capacitor sample the intermediate signal, and during an integration phase, the first integrating capacitor and the second integrating capacitor are connected in parallel.

11. The recording module of claim 10, wherein an integration coefficient of the SDM is a sum of capacitance values of the first sampling capacitor and the second sampling capacitor divided by a sum of capacitance values of the first integrating capacitor and the second integrating capacitor.

12. The recording module of claim 10, wherein two terminals of the first sampling capacitor are a first node and a second node, respectively, two terminals of the second sampling capacitor are a third node and a fourth node, respectively, and the SDM further comprises:
a first switch coupled between the driving circuit and the first node;
a second switch coupled between the first node and a first reference voltage;
a third switch coupled between the second node and a second reference voltage;
a fourth switch coupled between the second node and the first input terminal;
a fifth switch coupled between the driving circuit and the third node;
a sixth switch coupled between the third node and the first reference voltage;
a seventh switch coupled between the fourth node and the second reference voltage;
an eighth switch coupled between the fourth node and the first input terminal; and
a ninth switch coupled between the first input terminal and the second integrating capacitor.

13. The recording module of claim 12, wherein during the sampling phase, the first switch, the third switch, the fifth switch, the seventh switch, and the ninth switch are turned on, and the second switch, the fourth switch, the sixth switch, and the eighth switch are turned off; during the integration phase, the first switch, the third switch, the fifth switch, and the seventh switch are turned off, and the second switch, the fourth switch, the sixth switch, the eighth switch, and the ninth switch are turned on.

14. The recording module of claim 9, wherein the operational amplifier is a first operational amplifier, the output terminal is a first output terminal, and the driving circuit comprises:
a second operational amplifier having a third input terminal, a fourth input terminal, and a second output terminal;
a first resistor coupled between the third input terminal and the second output terminal;
a second resistor having a first terminal and a second terminal, wherein the first terminal receives the input signal, and the second terminal is coupled to the third input terminal; and
a current source coupled to the second operational amplifier;
wherein when the SDM simultaneously uses the first sampling capacitor and the second sampling capacitor to sample the intermediate signal, the current source provides a first bias current; when the SDM uses only one of the first sampling capacitor and the second sampling capacitor to sample the intermediate signal, the current source provides a second bias current.

15. The recording module of claim 14, wherein the first bias current is greater than the second bias current.

16. The recording module of claim 9, wherein the operational amplifier is a first operational amplifier, the output terminal is a first output terminal, and the driving circuit comprises:
a second operational amplifier having a third input terminal and a second output terminal and comprising a plurality of input stages and a plurality of output stages;
a first resistor having a first terminal and a second terminal, wherein the first terminal is coupled to the third input terminal, and the second terminal is coupled to the second output terminal; and
a second resistor having a third terminal and a fourth terminal, wherein the third terminal receives the input signal, and the second terminal is coupled to the third input terminal;
wherein when the SDM simultaneously uses the first sampling capacitor and the second sampling capacitor to sample the intermediate signal, there are M units connected in parallel among the plurality of input stages, and there are N units connected in parallel among the plurality of output stages, where M and N are integers greater than or equal to two; and when the SDM uses only one of the first sampling capacitor and the second sampling capacitor to sample the intermediate signal, there are X units connected in parallel among the plurality of input stages, and there are Y units connected in parallel among the plurality of output stages, where X and Y are integers greater than or equal to one.

17. The recording module of claim 16, wherein M is greater than X, and N is greater than Y.

18. The recording module of claim 9 further comprising:
a third sampling capacitor, wherein two terminals of the third sampling capacitor are respectively coupled to the driving circuit and the first input terminal; and
a third integrating capacitor, wherein two terminals of the third integrating capacitor are respectively coupled to the first input terminal and the output terminal.

19. The recording module of claim 9, wherein a ratio of the first sampling capacitor to the second sampling capacitor is substantially equal to a ratio of the first integrating capacitor to the second integrating capacitor.

20. The recording module of claim 9, wherein during a sampling phase, the first sampling capacitor samples the intermediate signal, and the second sampling capacitor does not sample the intermediate signal; and during an integration phase, the first integrating capacitor is not connected in parallel with the second integrating capacitor.
